(19) United States
(12) Patent Application Publication
(10) Pub. No.: US 2011/0048786 A1
(43) Pub. Date: Mar. 3, 2011

(54) PRINTED CIRCUIT BOARD HAVING A BUMP AND A METHOD OF MANUFACTURING THE SAME

(75) Inventors: Suk Hyeon Cho, Gyunggi-do (KR); Jin Yong Ahn, Gyunggi-do (KR); Soon Oh Jung, Gyunggi-do (KR); Dong Ju Jeon, Seoul (KR); Ki Hwan Kim, Gyunggi-do (KR); Byung Moon Kim, Gyunggi-do (KR)

(73) Assignee: SAMSUNG ELECTRO-MECHANICS CO., LTD., Gyunggi-do (KR)

(21) Appl. No.: 12/870,137

(22) Filed: Aug. 27, 2010

(30) Foreign Application Priority Data
Aug. 31, 2009 (KR) 10-2009-0081179
Jul. 28, 2010 (KR) 10-2010-0072923

(51) Int. Cl. H05K 1/11; H05K 3/10

(52) U.S. Cl. 174/261; 29/846

(57) ABSTRACT

Disclosed herein is a printed circuit board having a bump and a method of manufacturing the same. The printed circuit board having a bump includes an insulating layer into which an inner circuit layer is impregnated; a protective layer that is formed under the insulating layer and has an opening exposing a pad unit of the inner circuit layer; and a bump that is integrally formed with the pad unit and is protruded from the inner side of the protective layer to the outside of the protective layer through the opening. The bump is integrally formed with the pad unit, thereby improving bonding strength between the bump and the printed circuit board, and the surface area of the bump is formed to be wide, thereby improving bonding strength between a solder ball and the printed circuit board.

### CROSS REFERENCE TO RELATED APPLICATION

This application claims the benefit of Korean Patent Application No. 10-2010-0072923, filed on Jul. 28, 2010, entitled “A Printed Circuit Board Having A Bump And A Method Of Manufacturing The Same”, Korean Patent Application No. 10-2009-0081179, filed on Aug. 31, 2009, entitled “A Printed Circuit Board Comprising A Bump And A Method Of Manufacturing The Same”, which are hereby incorporated by reference in its entirety into this application.

### BACKGROUND OF THE INVENTION

1. Technical Field

The present invention relates to a printed circuit board having a bump and a method of manufacturing the same.

2. Description of the Related Art

Recently, electronic products have become multifunctional and high-speed at a higher rate. In order to cope with such a trend, a semiconductor chip and a printed circuit board mounted with a semiconductor chip connecting the semiconductor chip to a main substrate have been also developed at a very higher rate.

High-speed and high integration of the printed circuit board are requested for developing the printed circuit board mounted with the semiconductor chip. In order to meet the requirements, the printed circuit board is requested to be light and slim and have a fine pattern, excellent electrical characteristics, high reliability, high-speed signal transfer structure, or the like. Therefore, there are many demands for improving and developing the printed circuit board.

Meanwhile, in the prior art, a core substrate into which a core layer is inserted to prevent warpage of the printed circuit board has been mainly used. However, the core substrate has problems in view of thickness, for example, being too thick, and a long signal processing time. Therefore, in order to cope with thinning of the printed circuit board according to the development thereof, a coreless substrate that can reduce the entire thickness and the signal processing time by removing the core layer has been in the limelight.

FIG. 1 is a cross-sectional view of a printed circuit board according to the prior art. Hereinafter, a method of manufacturing the printed circuit board will be described with reference to the figure.

As shown in FIG. 1, the printed circuit board according to the prior art is configured to include an insulating layer 5, a circuit layer 4 that is formed on the insulating layer 5 and includes a pad unit 3, a solder resist layer 2 that is formed on the outermost layer of the printed circuit board and protects the circuit layer 4, and a solder ball 1 that is connected with the pad unit 3 and connects the printed circuit board to an external device.

The method of manufacturing the printed circuit board constituted as above will be described.

First, the multi-layer or single-layer insulating layer 5 and circuit layer 4 are stacked on a carrier (not shown).

Then, the solder resist layer 2, which is formed on the outermost layer, is formed to surround the circuit layer 4.

Then, an opening that exposes the pad unit 3 of the solder resist layer 2 is machined.

Then, the solder ball 1 is formed by being subject to printing and reflow processes of a solder paste.

Finally, the carrier is removed, thereby completing the manufacture of the printed circuit board having a solder ball.

However, in the case of the printed circuit board according to the prior art, a process of forming the opening that exposes the pad unit 3 of the solder resist layer 2 to the outside and processes of printing and reflowing the solder paste should be performed in order to form the solder ball 1, thereby increasing the manufacturing process and manufacturing costs.

In addition, the solder ball 1 is supported by only the pad unit 3 to have weak bonding strength between the solder ball 1 and the printed circuit board, thereby causing problems in that the solder ball 1 is easily broken due to external force such as shearing force or the like or is bent in the shearing force direction.

### SUMMARY OF THE INVENTION

The present invention has been made in an effort to provide a printed circuit board having a bump that is formed together with an inner circuit layer through one process without an additional process, the bump capable of functioning as an external connection terminal, and a method of manufacturing the same.

Further, the present invention has been made in an effort to provide a printed circuit board having a bump with large bonding strength between a solder ball and the printed circuit board when the solder ball is additionally bonded to the bump, and a method of manufacturing the same.

A printed circuit board having a bump according to a first preferred embodiment of the present invention includes: an insulating layer into which an inner circuit layer is impregnated; a protective layer that is formed under the insulating layer and has an opening exposing a pad unit of the inner circuit layer; and a bump that is integrally formed with the pad unit and is protruded from the inner side of the protective layer to the outside of the protective layer through the opening.

Herein, the protruded surface area of the bump is wider than the area of the opening of the protective layer.

Further, the bump has a shape of an electrical connection pin that is lengthened toward an outer side direction of the protective layer.

Further, the protective layer is a solder resist layer.

Further, the inner circuit layer and the bump are formed by a plating process.

Further, the printed circuit board having a bump further includes a metal layer that is formed on the surface of the bump, protruded to the outside.

A printed circuit board having a bump according to a second preferred embodiment of the present invention includes: an insulating layer into which an inner circuit layer is impregnated; a protective layer that is formed under the insulating layer and has an opening exposing a pad unit of the inner circuit layer; a bump that is integrally formed with the pad unit and is formed in the opening; and an electrical connection pin that is bonded to the top surface of the bump.

Herein, the bump and the electrical connection pin are plated and bonded.

A printed circuit board having a bump according to a third preferred embodiment of the present invention includes: an insulating layer into which an inner circuit layer is impregnated; a protective layer that is formed under the insulating layer and has an opening exposing a pad unit of the inner circuit layer; a bump that is integrally formed with the pad unit and is protruded from the inner side of the protective layer to the outside of the protective layer through the opening; and an outer circuit layer that is impregnated into the protective layer and of which one surface is exposed to the outside of the protective layer.

Herein, the outer circuit layer includes a terminal unit and a dummy pattern, or both the terminal unit and the dummy pattern.

A method of manufacturing a printed circuit board having a bump according to a first preferred embodiment of the present invention includes: (A) providing a carrier formed with a groove, including a protective layer formed on one surface thereof; (B) forming a bump in the groove and forming an inner circuit layer including a pad unit connected to the bump on the protective layer simultaneously with forming the bump; (C) stacking an insulating layer on the protective layer on which the inner circuit layer is formed so that the inner circuit layer is impregnated into the insulating layer; and (D) removing the carrier.

Herein, step (A) includes: (A1) providing a carrier formed with a first release layer; (A2) forming a protective layer on the carrier; (A3) machining a groove in the carrier, including the protective layer; and (A4) forming a metal layer on the inner circumferential surface of the groove.

Further, at step (B), the bump has a shape of an electrical connection pin.

Further, a stopper layer is further included in the carrier.

Further, the stopper layer is made of metal or ceramic.

Further, the surface area of the bump formed in the groove is formed to be wider than the surface of the opening of the protective layer.

Further, at step (B), the bump and the inner circuit layer are formed by a plating process.

Further, the protective layer is a solder resist layer.

Further, step (A) includes: (A1) forming a protective layer on a carrier; and (A2) forming a groove in the carrier, including the protective layer.

Further, step (A) includes: (A1) forming a groove in a carrier; (A2) forming a protective layer on the carrier; and (A3) forming an opening in a position corresponding to the groove of the protective layer.

A method of manufacturing a printed circuit board having a bump according to a second embodiment of the present invention includes: (A) providing a carrier into which an electrical connection pin is inserted but one surface of the electrical connection pin is exposed to the outside; (B) forming a protective layer on the carrier where one surface of the electrical connection pin is exposed and machining a hole in the protective layer; (C) forming a bump connected to the electrical connection pin in the hole and forming an inner circuit layer including a pad unit connected to the bump on the protective layer simultaneously with forming the bump; (D) stacking an insulating layer on the protective layer on which the inner circuit layer is formed so that the inner circuit layer is impregnated into the insulating layer; and (E) removing the carrier.

In this case, the bump and the inner circuit layer are formed by a plating process, and the electrical connection pin and the bump are plated and bonded.

A method of manufacturing a printed circuit board having a bump according to a third embodiment of the present invention includes: (A) providing a carrier that has an outer circuit layer formed on one surface thereof and a groove, including a protective layer into which the inner circuit layer is impregnated; (B) forming a bump in the groove and forming an inner circuit layer that includes a pad unit connected to the bump on the protective layer simultaneously with forming the bump; (C) stacking an insulating layer on the protective layer on which the inner circuit layer is formed so that the inner circuit layer is impregnated into the insulating layer; and (D) removing the carrier.

In this case, the outer circuit layer includes a terminal unit and a dummy pattern, or both the terminal unit and the dummy pattern.

Further, step (A) includes: (A1) forming an outer circuit layer on a carrier; (A2) forming a protective layer on the carrier so that the outer circuit layer is impregnated; and (A3) forming a groove in the carrier, including the protective layer.

Further, step (A) includes: (A1) forming a groove in a carrier; (A2) forming an outer circuit layer on the carrier; (A3) forming a protective layer on the carrier so that the outer circuit layer is impregnated; and (A4) forming an opening in a position corresponding to the groove of the protective layer.

### BRIEF DESCRIPTION OF THE DRAWINGS

FIG. 1 is a cross-sectional view of a printed circuit board according to the prior art;

FIG. 2 is a cross-sectional view of a printed circuit board having a bump according to a first preferred embodiment of the present invention;

FIG. 3 is a cross-sectional view of a printed circuit board having a bump according to a second preferred embodiment of the present invention;

FIG. 4 is a cross-sectional view of a printed circuit board having a bump according to a third preferred embodiment of the present invention;

FIGS. 5 to 11 are process cross-sectional views for explaining a method of manufacturing the printed circuit board having a bump shown in FIG. 2;

FIGS. 12 to 16 are process cross-sectional views for explaining a method of manufacturing the printed circuit board having a bump shown in FIG. 3; and

FIGS. 17 to 24 are process cross-sectional views for explaining a method of manufacturing the printed circuit board having a bump shown in FIG. 4.

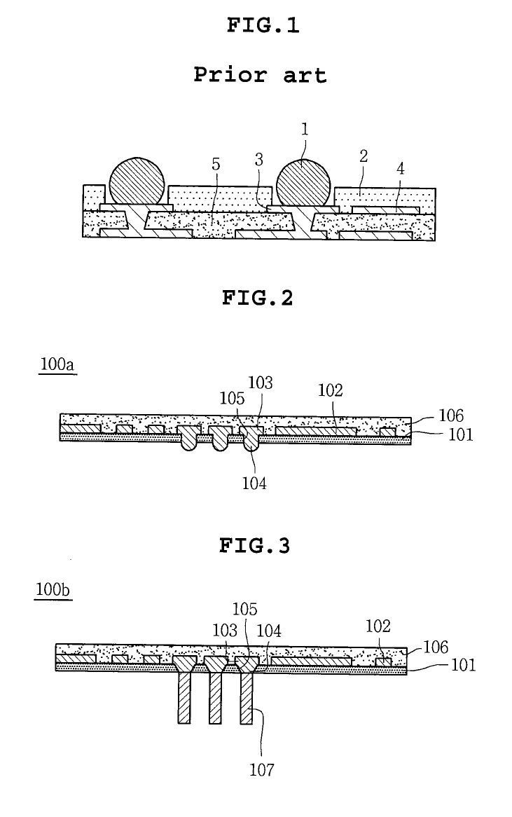

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Structure of Printed Circuit Board Having Bump

FIG. 2 is a cross-sectional view of a printed circuit board 100a having a bump according to a first preferred embodiment of the present invention. Hereinafter, the printed circuit board 100a having a bump according to the present embodiment will be described with reference to the figure.

As shown in FIG. 2, the printed circuit board 100a having a bump according to the present embodiment is configured to include a protective layer 101, an insulating layer 106 impregnated with an inner circuit layer 102, and a bump 104, wherein the bump 104 is integrally connected with a pad unit 103 of the inner circuit layer 102 to be protruded to the outside of the protective layer 101 through an opening 105 of the protective layer 101.

The protective layer 101 is a member that protects the inner circuit layer 102 and supports the bump 104.

In this case, the protective layer 101 may be formed of, for example, a solder resist layer so as to protect the inner circuit layer 102. In addition, the opening 105 that exposes the pad unit 103 of the inner circuit layer 102 may be formed in the protective layer 101.

The insulating layer 106, which is a member that is formed on the protective layer 101, is stacked by impregnating the inner circuit layer 102 formed on the protective layer 101.

In this case, the insulating layer 106 may use composite polymer resin that is generally used as an interlayer isolation material. For example, the insulating layer 106 may use prefreg, such that the printed circuit board 100a having a bump can be manufactured to be thinner. Alternatively, the insulating layer 106 may use an Ajinomoto Build up Film (ABF). In addition, the insulating layer 106 may use epoxy-based resin such as FR-4, Bismaleimide Triazine (BT), or the like, but it is not particularly limited thereto.

Meanwhile, the present embodiment will describe a case in which the insulating layer 106 and the inner circuit layer 102 are formed in a single layer, a multi-layer printed circuit board may also be configured by stacking a build-up layer including a plurality of insulating layers and circuit layers.

The inner circuit layer 102 is a member that is formed on the protective layer 101 to be impregnated into the insulating layer 106.

In this case, the inner circuit layer 102 includes the pad unit 103 that is exposed through the opening 105 of the protective layer 101, wherein the pad unit 103 may be integrally connected with the bump 104 through the opening 105. In addition, the inner circuit layer 102 may be made of, for example, a conductive metal such as gold, silver, copper, nickel, or the like.

Meanwhile, the pad unit 103 should not be always wider than the surface area of the bump 104 but the pad unit 103 and the bump 104 have the same surface area, thereby making it possible to manufacture a printed circuit board having a padless type bump 104.

The bump 104 is a member that connects between an external device (not shown) and the pad unit 103, that is, between an external device (not shown) and the printed circuit board 100a having a bump.

Herein, the bump 104 may function as an external connection terminal as it is. Alternatively, a solder ball (not shown) is additionally formed on the bump 104, such that a semiconductor chip, an active device, a passive device, or the like may be connected thereto. In addition, the bump 104 has a shape that protrudes into the outside of the protective layer 101, while being integrally connected with the pad unit 103 through the opening 105 of the protective layer 101. In this case, the bump 104 is integrally formed with the pad unit 103 by, for example, a plating process. As a result, bonding strength between the bump 104 and the printed circuit board 100a may be relatively large.

Meanwhile, it is preferable that the protruded surface area of the bump 104 is wider than the surface of the opening 105 of the protective layer 101. More specifically, when the surface area of the bump 104 is formed to be wider, an area in which the solder ball is in contact with the bump 104 may be formed to be wide when a solder ball is bonded onto the bump 104. Therefore, when the solder ball is applied with external force such as shearing force or the like, a phenomenon that the solder ball is broken or separated may be reduced as compared to a case in which the surface area of the bump 104 is small.

In addition, the bump 104 may have a shape of an electrical connection pin by reducing a diameter of the cross-section of the bump 104 and lengthening thereof. The electrical connection pin becomes a portion to be connected with an external device, for example, a semiconductor chip, an active device, and a passive device. In this case, the solder ball may not be required.

In addition, the bump 104 may be configured in a cone shape. In this case, the bump 104 may be bonded to the terminal of the external device using an ultrasonic bonding technology. At this time, vibration energy is concentrated on one point, such that the bump 104 can be more easily bonded to the terminal of the external device as compared to a case in which a surface is in contact with another surface.

Meanwhile, the bump 104 is shown to have a cylindrical shape at the opening 105 of the protective layer 101 and have an almost hemispherical shape at the portion protruded into the outside in FIG. 2. However, the present invention is not limited thereto but the bump 104 may be implemented to have various shapes.

FIG. 3 is a cross-sectional view of a printed circuit board 100b having a bump according to a second preferred embodiment of the present invention. Hereinafter, the printed circuit board 100b having a bump according to the present embodiment will be described with reference to the figure. Herein, like reference numerals will designate like or corresponding components and the description overlapping with the first embodiment will be omitted.

As shown in FIG. 3, the printed circuit board 100b having a bump according to the present embodiment is configured to include a protective layer 101, an insulating layer 106 impregnated with an inner circuit layer 102, a bump 104, and an electrical connection pin 107, wherein the bump 104 is bonded to the electrical connection pin 107.

In the present embodiment, the bump 104 may, for example, have a height equal to an outer surface of the protective layer 101, while not being protruded to the outside of the protective layer 101, and the electrical connection pin 107 may be bonded to the bump 104 by, for example, a plating process, different from the first embodiment. Alternatively, the bump 104 may be formed to be protruded to the outside of the protective layer 101 and the electrical connection pin 107 may be bonded to the top surface of the protruded bump 104.

The electrical connection pin 107, which serves to be directly connected with an external device (not shown) or to be connected with an external device (not shown) through a solder ball, is formed to be connected with the bump 104.

Herein, when the electrical connection pin 107 is bonded, there is no need to make the bump 104 long in order to have an electrical connection pin, different from the first embodiment. As a result, the manufacturing process thereof can be simplified. Meanwhile, the electrical connection pin 107 may be formed to have a polygonal column such as a triangular column, a square column, or the like, in addition to the cylindrical shape.

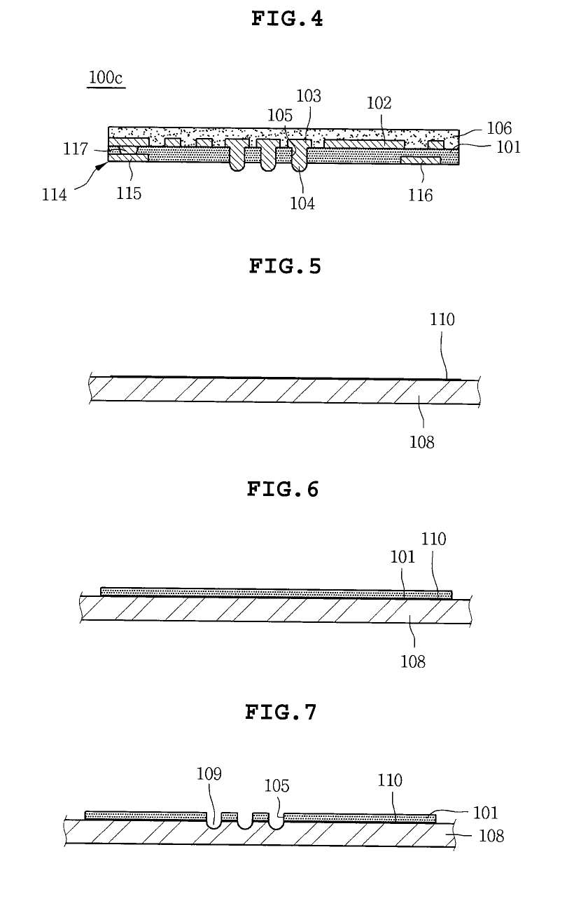

FIG. 4 is a cross-sectional view of a printed circuit board 100c having a bump according to a third preferred embodiment of the present invention. Hereinafter, the printed circuit board 100c having a bump according to the present embodiment will be described with reference to the figure. Herein, like reference numerals will designate like or corresponding components and the description overlapping with the first embodiment and the second embodiment will be omitted.

As shown in FIG. 4, the printed circuit board 100c having a bump according to the present embodiment is configured to include a protective layer 101, an insulating layer 106 impregnated with an inner circuit layer 102, a bump 104, and an outer circuit layer 114, wherein the outer circuit layer 114 is impregnated into the protective layer 101.

The outer circuit layer 114 is formed to be impregnated into the protective layer 101, while one surface thereof being exposed to the outside of the protective layer 101.

Herein, the outer circuit layer 114 may include a terminal unit 115 and a dummy pattern 116. The terminal unit 115, which is a portion where a passive device or the like is directly connected with the printed circuit board 100c having a bump, may be electrically connected with the inner circuit layer 102 through a via 117. In addition, the dummy pattern 116 is a portion not electrically connected with another circuit layer not to be operated in view of a circuit. The dummy pattern 116 supports both ends of the printed circuit board 100c having a bump, thereby making it possible to reduce warpage phenomenon of the printed circuit board 100c having a bump.

Method of Manufacturing Printed Circuit Board Having Bump

FIGS. 5 to 11 are process cross-sectional views for explaining a method of manufacturing the printed circuit board 100a having a bump according to a first preferred embodiment of the present invention. Hereinafter, the method of manufacturing the printed circuit board 100a having a bump according to the present embodiment will be described with reference to the figures.

First, as shown in FIG. 5, a first release layer 110 is formed on a carrier 108.

In this case, the carrier 108 serves to perform supporting function during a manufacturing process of the printed circuit board 100a. The carrier 108 may contain, for example, stainless steel or an organic resin material. In particular, in the case of stainless steel, there is an advantage in that it can be easily separated from the printed circuit board 100a.

In addition, when the carrier 108 is removed from the printed circuit board 100a, the first release layer 110 serves to easily separate the carrier 108 therefrom so that the printed circuit board 100a, in particular, the protective layer 101, can maintain its designed shape without being damaged. Herein, the first release layer 110 may be formed by, for example, a release coating or a plasma processing. Alternatively, the first release layer 101 may be a polyethylene terephthalate sheet applied with Si based release agents.

Then, as shown in FIG. 6, the protective layer 101 is formed on the carrier 108 on which the first release layer 110 is formed.

At this time, it is preferable that the protective layer 101 has a length and an area smaller than those of the first release layer 110 so that the protective layer 101 is easily separated from the carrier 108.

Then, as shown in FIG. 7, grooves 109 are machined in the carrier 108, including the protective layer 101 and the first release layer 110.

In this case, the groove 109 is formed to have a shape of the opening 105 in the protective layer 101 and have a dug shape by removing a portion of the carrier 108 in the carrier 108. Therefore, if the carrier 108 is subsequently separated, the bump 104 protruded to the outside of the protective layer 101 is formed.

In addition, it is preferable that the inner surface of the groove 109 formed in the carrier 108 is wider than the cross-section of the opening 105 formed on the protective layer 101. This the reason that when the bump 104 is formed by plating the groove 109 and a solder ball is bonded to the bump 104, the wide bonding surface between the solder ball and the bump 104 is advantageous in view of the bonding strength between the solder ball and the printed circuit board 100c.

In addition, the groove 109 may be machined by laser, imprinting or drilling. At this time, in connection with a stopper layer to be described below, it is preferable that the groove 109 is machined by laser. More specifically, a stopper layer (not shown) may further be included in the carrier 108. When the groove 109 is machined in the carrier 108, including the protective layer 101, the stopper layer cannot be penetrated by laser, as a result, it is machined only up to the top surface thereof. Therefore, the grooves 109 have a constant depth, thereby making it possible to form the bump 104 having a constant height. Herein, it is more preferable that the stopper layer is made of materials that cannot be machined by laser, such as metals, ceramics, or composite materials.

Meanwhile, the present embodiment describes the case in which the protective layer 101 is formed on the carrier 108 and then the grooves 109 are formed in the carver 108, including the protective layer 101 but the present invention is not limited thereto. For example, the protective layer 101 is formed after previously forming the grooves 109 in the carrier 108 and then, the openings 105 are formed in the positions of the protective layer 101, corresponding to the grooves 109, thereby providing the carrier 108 formed with the grooves 109, including the protective layer 101.

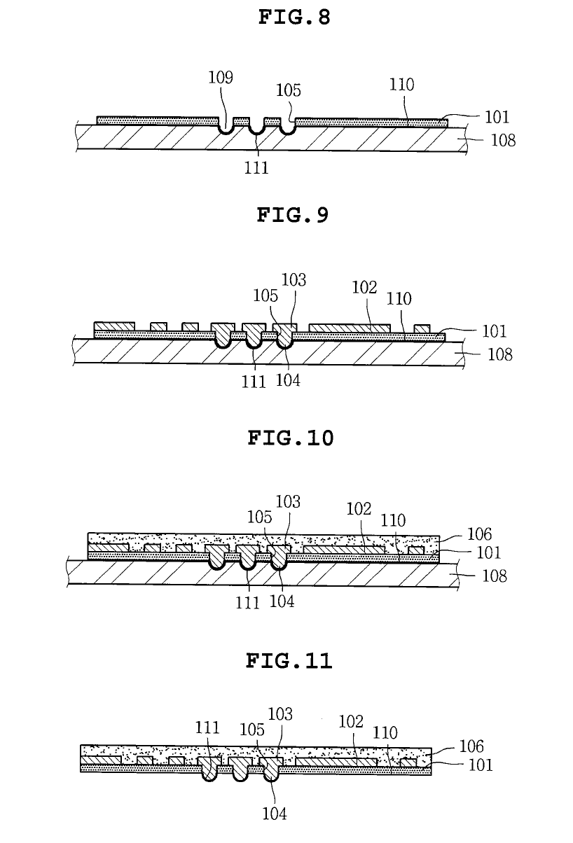

Then, as shown in FIG. 8, a metal layer 111 is formed on the inner circumferential surface of the groove 109.

In this case, the metal layer 111 is bonded to the bump 104 even after the carrier 108 to be described below is separated, and the metal layer 111 is thus previously formed in a final product without forming an additional solder ball, thereby making it possible to reduce processing costs and time. Herein, it is preferable that the metal layer 111 is a solder layer having tin as a main component.

Then, as shown in FIG. 9, a plating layer is formed on the protective layer 101 including the inside of the groove 109 and the plating layer is patterned, thereby forming the bump 104 formed in the groove 109 and the inner circuit layer 102. Herein, the plating process is performed once.

In this case, for example, an electroless plating process, a plating resist forming process, a patterning process, and an electroplating process are performed on the protective layer 101, such that the bump 104 is formed in the groove 109, the pad unit 103 is formed on the portion connected to the bump 104, and other necessary outer circuit layer 102 is formed.

Meanwhile, since the bump 104 is formed by a plating process, the protective layer 101 is very closely bonded to the bump 104 barely having an interval therebetween, thereby narrowing the interval between the bumps 104 as compared to the prior method generally considering exposure tolerance.

Then, as shown in FIG. 10, the insulating layer 106 is stacked on the protective layer 101 so that the inner circuit layer 102 formed on the protective layer 101 is impregnated into the insulating layer 106.

In this case, the insulating layer 106 may be pressed and stacked using a press plate of which surface is flat such as a stainless plate, while being heated at a softening temperature or more.

Then, as shown in FIG. 11, the carrier 108 not affecting the operation of the printed circuit board 100a having a bump is separated from the printed circuit board 100a having a bump.

The printed circuit board 100a having a bump as shown in FIG. 11 according to a first preferred embodiment of the present invention is manufactured through the manufacturing process as described above.

In addition, a multi-layer printed circuit board may also be manufactured by forming a build-up layer including a plurality of insulating layers and circuit layers on the printed circuit board 100a.

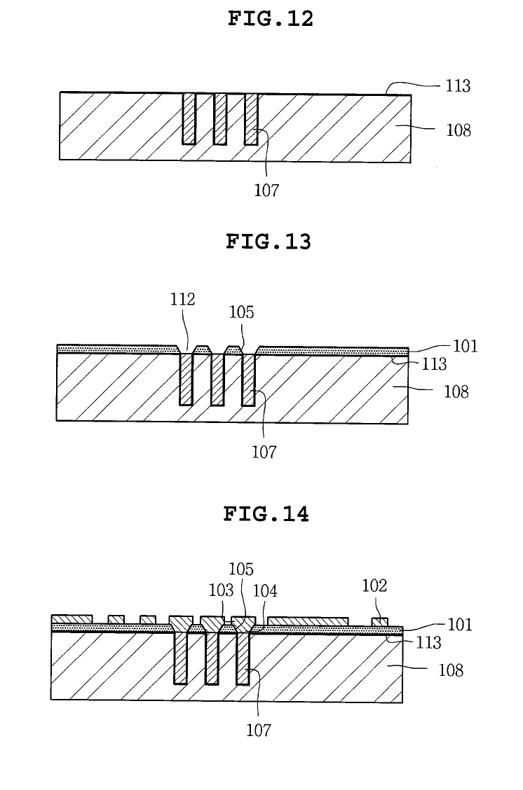

FIGS. 12 to 16 are process cross-sectional views for explaining a method of manufacturing the printed circuit board 100b having a bump according to a second preferred embodiment of the present invention. Hereinafter, the method of manufacturing the printed circuit board 100b having a bump according to the present embodiment will be described with reference to the figures. Herein, like reference numerals will designate like or corresponding components and the description overlapping with the first embodiment will be omitted.

First, as shown in FIG. 12, a carrier 108 into which electrical connection pins 107 are inserted from the outer surface thereof is provided.

In this case, the electrical connection pins 107 are previously inserted into the carrier 108 through a preparatory work and one surface of the electrical connection pin 107 is formed to be exposed to the outer surface of the carrier 108. In addition, the electrical connection pin 107 may be made of, for example, the same material as that of the inner circuit layer 102 and the bump 104.

Meanwhile, it is preferable that a second release layer 113 is formed between the carrier 108 and the electrical connection pins 107 and on the top surface of the carrier 108 except portions into which the electrical connection pins 107 are inserted. The reason is that the electrical connection pins 107 can be easily separated from the carrier 108 when removing the carrier 108 later.

Then, as shown in FIG. 13, a protective layer 101 is formed on the outer surface of the carrier 108 into which the electrical connection pin 107 is inserted and holes 112 are machined in the protective layer 101.

In this case, similar to the first embodiment, it is preferable that the hole 112 is machined by laser and it should be noted that the carrier 108 is to be machined only up to the outer surface thereof. Meanwhile, the electrical connection pin 107 is made of metal, such that the electrical connection pin 107 can function as a stopper layer against laser.

Herein, the hole 112 may substantially have the shape of the opening 105 in the protective layer 101.

Then, as shown in FIG. 14, a plating layer is formed on the protective layer 101 including the inside of the hole 112 and the plating layer is patterned, thereby forming the bump 104 formed in the hole 112 and the inner circuit layer 102, the bump 104 being bonded to the electrical connection pin 107.

In this case, when the bump 104 is formed in the hole 112, the bump 104 may be plated and bonded to the electrical connection pin 107 by applying heat and pressure.

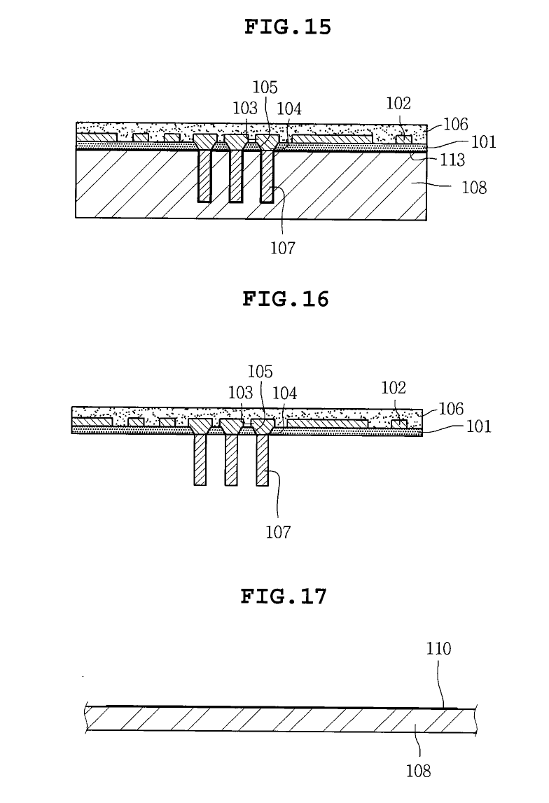

Then, as shown in FIGS. 15 and 16, the insulating layer 106 is stacked on the protective layer 101 so that the inner circuit layer 102 is impregnated into the insulating layer 106 and the carrier 108 is removed from the printed circuit board 100b.

The printed circuit board 100b having a bump as shown in FIG. 16 according to a second preferred embodiment of the present invention is manufactured through the manufacturing process as described above.

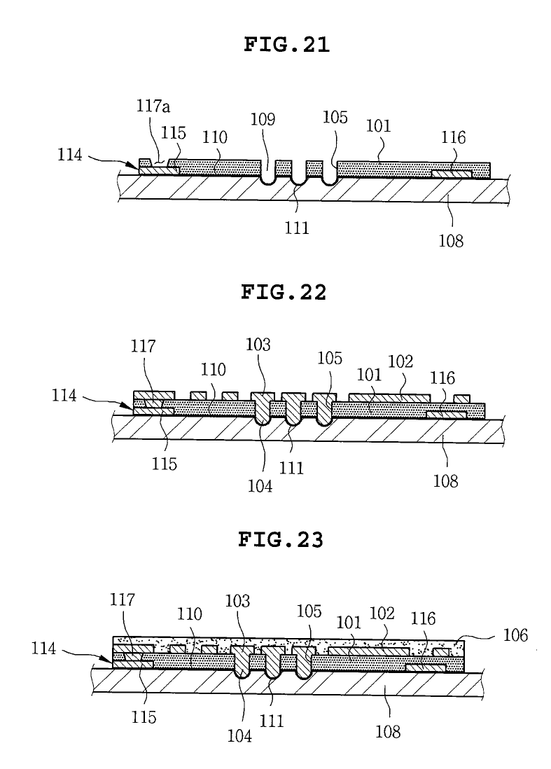

FIGS. 17 to 24 are process cross-sectional views for explaining a method of manufacturing the printed circuit board 100c having a bump according to a third preferred embodiment of the present invention. Hereinafter, the method of manufacturing the printed circuit board 100c having a bump according to the present embodiment will be described with reference to the figures. Herein, like reference numerals will designate like or corresponding components and the description overlapping with the first embodiment and the second embodiment will be omitted.

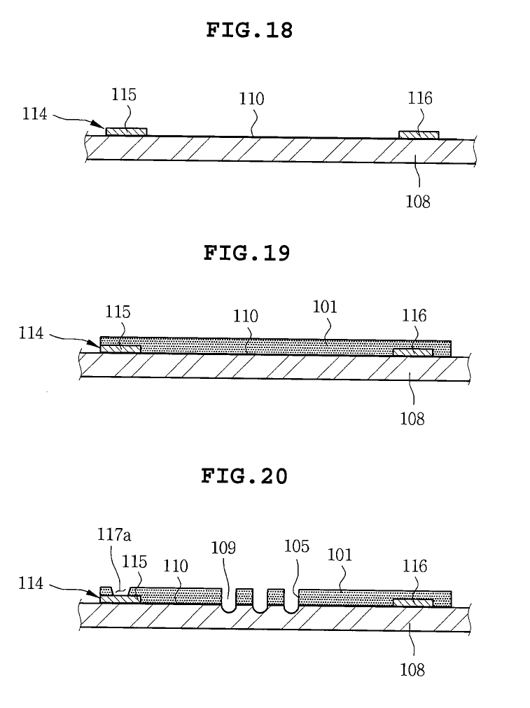

First, as shown in FIGS. 17 and 18, a first release layer 110 is formed on a carrier 108 and an outer circuit layer 114 is formed on the first release layer 110.

In this case, the outer circuit layer 114 may be formed by a well-known method such as a semi-additive method, a subtractive method, an additive method, or the like, and may be made of electrically conductive metal.

Then, as shown in FIGS. 19 to 21, a protective layer 101 is formed on the first release layer 110 on which the outer circuit layer 114 is formed, a groove 109 and a via hole 117a are machined in the protective layer 101, and a metal layer 111 is formed on the inner circumferential surface of the groove 109.

In this case, the via hole 117a and the groove 109 may be formed at one time by, for example, laser, and be also formed by different methods.

Meanwhile, the present embodiment describes a case in which the outer circuit layer 114 and the protective layer 101 are formed on the carrier 108 and then the grooves 109 are formed in the carrier 108, including the protective layer 101. However, for example, the grooves 109 are previously formed in the carrier 108 and the outer circuit layer 114 and the protective layer 101 are formed, and then the openings 105 are formed in the positions of the protective layer 101 corresponding to the grooves 109, thereby making it also possible to provide the carrier 108 formed with the grooves 109, including the protective layer 101.

Then, as shown in FIGS. 22 and 23, the bump 104 protruded into the outside of the protective layer 101, the inner circuit layer 102, and the via 117 that connects the inner circuit layer 102 to the outer circuit layer 114 may be formed in the groove 109, on the protective layer 101, and the via hole 117a by, for example, a plating process, once. Further, an insulating layer 106 is stacked on the protective layer 101 so that the inner circuit layer 102 is impregnated into the insulating layer 106.

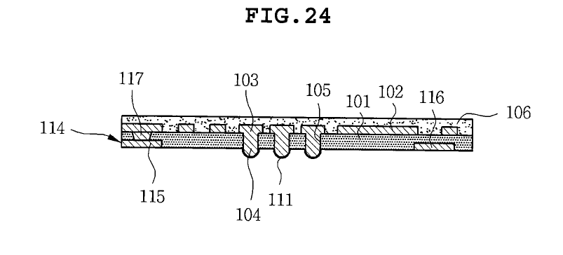

Then, as shown in FIG. 24, the carrier 108 is separated from the printed circuit board 100c having a bump.

The printed circuit board 100c having a bump as shown in FIG. 24 according to a third preferred embodiment of the present invention is manufactured through the manufacturing process as described above.

According to the present invention, the printed circuit board having a bump and a method of manufacturing the same forms the bump while simultaneously separating the carrier by machining the groove in the carrier, including the protective layer, to form the bump capable of functioning as an external connection terminal through one process without an additional process, together with the circuit layer, thereby making it possible to reduce manufacturing time and manufacturing costs.

In addition, according to the present invention, the bump is integrally formed with the pad unit, thereby making it possible to improve bonding strength between the bump and the printed circuit board. In particular, when the solder ball is additionally bonded to the bump, the surface area of the bump is wide to increase the bonding surface between the solder ball and the bump, such that the bonding strength between the solder ball and the printed circuit board is increased, as a result, required strength can be obtained even though the solder ball becomes small.

In addition, according to the present invention, the release layer is formed on the carrier to allow the carrier to be easily separated, thereby making it possible to maintain a designed shape thereof without damaging the protective layer.

In addition, according to the present invention, the bump is lengthened to have a shape of an electrical connection pin or the bump and the electrical connection pin are plated and bonded, thereby making it possible to simply form the electrical connection pin through one process.

In addition, according to the present invention, the stopper layer is provided in the carrier, thereby making it possible to form the bump having a constant height.

In addition, according to the present invention, the outer circuit layer of which one surface is exposed to the outside is impregnated into the protective layer, thereby making it possible to connect a passive device or the like to a terminal unit of the outer circuit layer or reduce warpage phenomenon of the printed circuit board by including the dummy pattern.

In addition, according to the present invention, the bump is formed by a plating process to be closely bonded to the protective layer to barely have an interval therebetween, thereby making it possible to further narrow the interval between the bumps.

In addition, according to the present invention, when the bump is configured in a cone shape and is bonded to the terminal of an external device by an ultrasonic bonding technology, vibration energy is concentrated on one point, thereby making it possible to more easily bond the bump to the terminal of the external device as compared to a case in which a surface is in contact with a surface.

Although the preferred embodiments of the present invention have been disclosed for illustrative purposes, they are for specifically explaining the present invention and thus a printed circuit board having a bump and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board having a bump, comprising:
an insulating layer into which an inner circuit layer is impregnated;
a protective layer that is formed under the insulating layer and has an opening exposing a pad unit of the inner circuit layer; and
a bump that is integrally formed with the pad unit and is protruded from the inner side of the protective layer to the outside of the protective layer through the opening.

2. The printed circuit board having a bump as set forth in claim 1, wherein the protruded surface area of the bump is wider than the area of the opening of the protective layer.

3. The printed circuit board having a bump as set forth in claim 1, wherein the bump has a shape of an electrical connection pin that is lengthened toward an outer side direction of the protective layer.

4. The printed circuit board having a bump as set forth in claim 1, wherein the protective layer is a solder resist layer.

5. The printed circuit board having a bump as set forth in claim 1, wherein the inner circuit layer and the bump are formed by a plating process.

6. The printed circuit board having a bump as set forth in claim 1, further comprising a metal layer that is formed on the surface of the bump, protruded to the outside.

7. A printed circuit board having a bump, comprising:
an insulating layer into which an inner circuit layer is impregnated;
a protective layer that is formed under the insulating layer and has an opening exposing a pad unit of the inner circuit layer;
a bump that is integrally formed with the pad unit and is formed in the opening; and
an electrical connection pin that is bonded to the top surface of the bump.

8. The printed circuit board having a bump as set forth in claim 7, wherein the bump and the electrical connection pin are plated and bonded.

9. A printed circuit board having a bump, comprising:
an insulating layer into which an inner circuit layer is impregnated;
a protective layer that is formed under the insulating layer and has an opening exposing a pad unit of the inner circuit layer;
a bump that is integrally formed with the pad unit and is protruded from the inner side of the protective layer to the outside of the protective layer through the opening; and
an outer circuit layer that is impregnated into the protective layer and of which one surface is exposed to the outside of the protective layer.

10. The printed circuit board having a bump as set forth in claim 9, wherein the outer circuit layer includes a terminal unit and a dummy pattern, or both the terminal unit and the dummy pattern.

11. A method of manufacturing a printed circuit board having a bump, comprising:
(A) providing a carrier formed with a groove, including a protective layer formed on one surface thereof;
(B) forming a bump in the groove and forming an inner circuit layer including a pad unit connected to the bump on the protective layer simultaneously with forming the bump;
(C) stacking an insulating layer on the protective layer on which the inner circuit layer is formed so that the inner circuit layer is impregnated into the insulating layer; and
(D) removing the carrier.

12. The method of manufacturing a printed circuit board having a bump as set forth in claim 11, wherein step (A) includes:
(A1) providing a carrier formed with a first release layer;
(A2) forming a protective layer on the carrier;
(A3) machining a groove in the carrier, including the protective layer; and
(A4) forming a metal layer on the inner circumferential surface of the groove.

13. The method of manufacturing a printed circuit board having a bump as set forth in claim 11, wherein at step (B), the bump has a shape of an electrical connection pin.

14. The method of manufacturing a printed circuit board having a bump as set forth in claim 11, wherein a stopper layer is further included in the carrier.

15. The method of manufacturing a printed circuit board having a bump as set forth in claim 14, wherein the stopper layer is made of metal or ceramic.

16. The method of manufacturing a printed circuit board having a bump as set forth in claim 11, wherein the surface area of the bump formed in the groove is formed to be wider than the surface of the opening of the protective layer.

17. The method of manufacturing a printed circuit board having a bump as set forth in claim 11, wherein at step (B), the bump and the inner circuit layer are formed by a plating process.

18. The method of manufacturing a printed circuit board having a bump as set forth in claim 11, wherein the protective layer is a solder resist layer.

19. The method of manufacturing a printed circuit board having a bump as set forth in claim 11, wherein step (A) includes:
(A1) forming a protective layer on a carrier; and
(A2) forming a groove in the carrier, including the protective layer.

20. A method of manufacturing a printed circuit board having a bump, comprising:
(A) providing a carrier into which an electrical connection pin is inserted but one surface of the electrical connection pin is exposed to the outside;
(B) forming a protective layer on the carrier where one surface of the electrical connection pin is exposed and machining a hole in the protective layer;
(C) forming a bump connected to the electrical connection pin in the hole and forming an inner circuit layer including a pad unit connected to the bump on the protective layer simultaneously with forming the bump;
(D) stacking an insulating layer on the protective layer on which the inner circuit layer is formed so that the inner circuit layer is impregnated into the insulating layer; and
(E) removing the carrier.

21. The method of manufacturing a printed circuit board having a bump as set forth in claim 20, wherein the bump and the inner circuit layer are formed by a plating process, and the electrical connection pin and the bump are plated and bonded.

22. A method of manufacturing a printed circuit board having a bump, comprising:
(A) providing a carrier that has an outer circuit layer formed on one surface thereof and a groove, including a protective layer into which the outer circuit layer is impregnated;
(B) forming a bump in the groove and forming an inner circuit layer that includes a pad unit connected to the bump on the protective layer simultaneously with forming the bump;
(C) stacking an insulating layer on the protective layer on which the inner circuit layer is formed so that the inner circuit layer is impregnated into the insulating layer; and
(D) removing the carrier.

23. The method of manufacturing a printed circuit board having a bump as set forth in claim 22, wherein the outer circuit layer includes a terminal unit and a dummy pattern, or both the terminal unit and the dummy pattern.

24. The method of manufacturing a printed circuit board having a bump as set forth in claim 22, wherein step (A) includes:
(A1) forming an outer circuit layer on a carrier;
(A2) forming a protective layer on the carrier so that the outer circuit layer is impregnated; and
(A3) forming a groove in the carrier, including the protective layer.

25. The method of manufacturing a printed circuit board having a bump as set forth in claim 22, wherein step (A) includes:
(A1) forming a groove in a carrier;
(A2) forming an outer circuit layer on the carrier;
(A3) forming a protective layer on the carrier so that the outer circuit layer is impregnated; and
(A4) forming an opening in a position corresponding to the groove of the protective layer.

26. The method of manufacturing a printed circuit board having a bump as set forth in claim 11, wherein step (A) includes:
(A1) forming a groove in a carrier;
(A2) forming a protective layer on the carrier; and
(A3) forming an opening in a position corresponding to the groove of the protective layer.
